(19) United States
(12) Patent Application Publication
(10) Pub. No.: US 2011/0089026 A1
(43) Pub. Date: Apr. 21, 2011

(54) TOUCH PANEL MANUFACTURING METHOD AND FILM FORMATION APPARATUS

(75) Inventors: Hirohisa Takahashi, Sammu-shi (JP); Satoru Ishibashi, Sammu-shi (JP)

(73) Assignee: ULVAC, INC., Chigasaki-shi (JP)

(21) Appl. No.: 13/000,105

(22) PCT Filed: Jul. 3, 2009
(86) PCT No.: PCT/JP2009/062206

§ 371 Date: Dec. 20, 2010

(30) Foreign Application Priority Data
Jul. 9, 2008 (JP) P2008-179372

(51) Int. Cl. C23C 14/34

(52) U.S. Cl. 204/192.29; 204/298.02; 204/298.17

(57) ABSTRACT

A touch panel manufacturing method is a method for manufacturing a touch panel including a transparent substrate having a main surface on which a transparent-electroconductive film is formed. The transparent-electroconductive film is formed on the main surface of the transparent substrate by carrying out sputtering using a target made of a zinc oxide-based material in a reactive gas atmosphere containing two or three gases selected from a group consisting of hydrogen gas, oxygen gas, and water vapor.

### BACKGROUND OF THE INVENTION

1. Field of the Invention

The present invention relates to a touch panel manufacturing method and to a film formation apparatus. In particular, the present invention relates to a method and a film formation apparatus for manufacturing a touch panel which is suitably provided on the display surface of a flat panel display (FPD), such as a liquid crystal display (LCD), and is capable of achieving ease of input with a typical writing tool or a finger, reduction in size, reduction in the area of a peripheral area excluding a display area, and reduction in manufacturing cost.

This application claims priority based on Japanese Patent Application No. 2008-179372 filed on Jul. 9, 2008, the disclosure of which is incorporated herein by reference.

2. Background Art

In recent years, with advances in flat panel displays (FPD), such as liquid crystal displays (LCD), there are increasingly new demands for a touch panel which is provided on the display surface of a flat panel display (FPD).

A new technique has been developed and proposed so as to meet the demands.

As a kind of touch panel, a resistance film type touch panel is known.

In the resistance film type touch panel, a pair of transparent substrates each having a main surface with a transparent-electroconductive film formed thereon are arranged to be opposite to each other at a predetermined gap such that the transparent-electroconductive films are opposite to each other.

A plurality of insulating spacers are arranged between the transparent-electroconductive films in a matrix.

The touch panel has a function in which, when a desired position on the viewing-side transparent substrate is depressed toward the display surface, a pair of transparent-electroconductive films are electrically connected to each other at the desired position, and information regarding the desired position is output to the outside as an electrical signal.

Conventionally, in the resistance film type touch panel, as the material for the transparent-electroconductive film, tin-added indium oxide (ITO: Indium Tin Oxide) is used in which 1 to 40% by mass of tin oxide is added to indium oxide.

However, indium (In) which is the raw material of ITO is a rare metal and is becoming difficult to obtain, and an increase in costs is being anticipated.

For this reason, with regard to a transparent conductive material as an alternative to ITO, a zinc oxide (ZnO)-based material which is abundant and inexpensive is attracting attention (for example, see Japanese Unexamined Patent Application, First Publication No. H09-87833).

The ZnO-based material is an n-type semiconductor in which ZnO is slightly reduced to be slightly deviated from a stoichiometric composition and an oxygen vacancy is formed in the ZnO crystal to emit free electrons, or B, Al, Ga, or the like added as an impurity enters the positions of the Zn ions of the ZnO crystal lattice and is ionized to emit free electrons, exhibiting conductivity.

The ZnO-based material is suitable for sputtering capable of forming a uniform film on a large substrate.

In the film formation apparatus, a target of an In₂O₃-based material, such as ITO, is changed to a target of a ZnO-based material, making it possible to form ZnO.

Additionally, since the ZnO-based material does not contain lower oxide (InO) having high insulation, such as an In₂O₃-based material, abnormality scarcely occurs at the time of sputtering.

In this touch panel, an anti-reflective film may be provided on the transparent substrate so as to increase anti-reflective performance.

The anti-reflective film has a layered structure in which a plurality of transparent films having different refractive indexes are superimposed on each other.

As a conventional anti-reflective film, for example, a configuration is used in which SiO having a refractive index of 1.45 to 1.46 and TiO having a refractive index of 2.3 to 2.55 are laminated.

When the layered structure of SiO and TiO is formed by sputtering using oxide targets, sputtering is carried out using an RF power source because the oxide targets have high resistance.

When the layered structure is formed using metal targets of Si and Ti which allows the use of a DC power source or an AC power source, layered films are formed by so-called reactive sputtering in which sputtering is carried out while a large amount of oxidative gas is introduced.

However, when the transparent-electroconductive film made of a conventional ZnO-based material is applied to a capacitance-type touch panel, transparency is comparable to a conventional ITO film, but there is a problem in that the specific resistance is high.

In order to decrease the specific resistance of the ZnO-based transparent-electroconductive film to a desired value, it is believed that a method in which a hydrogen gas serving as a reductive gas is introduced into the chamber at the time of sputtering, and the film is formed in the reductive atmosphere.

However, in this case, although the specific resistance of the resultant transparent-electroconductive film reliably decreases, metallic luster occurs slightly on the surface of the transparent-electroconductive film, and there is a problem in that transmittance is degraded.

Additionally, in the step of forming the anti-reflective film, when the targets of SiO and TiO are used, it is necessary to use an RF power source. For this reason, the film formation rate tends to be slow compared to a case where a DC power source or an AC power source is used.

In an apparatus using an RF power source, the power source cost tends to increase, and in some cases, the apparatus is complicated.

Furthermore, in a conventional film formation method, it is necessary to use two kinds of targets of SiO and TiO or two kinds of targets of Si and Ti, such that it is necessary to use two kinds of sputtering apparatuses.

### SUMMARY OF THE INVENTION

The invention was made in order to solve the above problems, and has an object to provide a touch panel manufacturing method and a film formation apparatus, where it is possible to decrease the specific resistance of a zinc oxide-based transparent-electroconductive film and to maintain transparency to visible light beams in a touch panel using a zinc oxide-based transparent-electroconductive film or an optical film such as an anti-reflective film.

In addition, another object of the present invention is to provide a touch panel manufacturing method and a film formation apparatus, where it is possible to form a transparent-electroconductive film or an optical film using a single apparatus even when an optical film, such as an anti-reflective film, is provided.

Additionally, another object of the present invention is to provide a touch panel manufacturing method and a film formation apparatus, where it is possible to form a film at a film formation rate greater than or equal to the film formation rate of a conventional transparent-electroconductive film or a conventional optical film.

Furthermore, another object of the present invention is to provide a touch panel manufacturing method and a film formation apparatus, where it is possible to form a multilayered optical film or a multilayered optical film and a transparent-electroconductive film by using one type of target and changing the type of gas to be introduced, in addition, it is possible to form a film at a film formation rate greater than the film formation rate of a conventional transparent-electroconductive film or a conventional optical film.

The inventors have intensively researched a touch panel to which a zinc oxide-based transparent-electroconductive film or an anti-reflective film is applied and have found that, when a target made of a zinc oxide-based material is used and a zinc oxide-based transparent-electroconductive film is formed by sputtering, sputtering is carried out in a reactive gas atmosphere containing two or three gases selected from a group consisting of hydrogen gas, oxygen gas, and water vapor, and sputtering is carried out on the condition that the ratio R(P_{H2}/P_{O2}) of the partial pressure (P_{H2}) of the hydrogen gas to the partial pressure (P_{O2}) of the oxygen gas satisfies the following expression (1), such that an excellent touch panel is obtained more than ever before, completing the present invention.

R=P_{H2}/P_{O2}≧5 (1)

Specifically, the inventors have found that, if sputtering is carried out under the above-described conditions, it is possible to decrease the specific resistance of the zinc oxide-based transparent-electroconductive film and to maintain transparency to visible light beams, and have also found that, if an optical film, such as a zinc oxide-based anti-reflective film, is formed in the same manner, it is possible to maintain transparency to visible light beams without causing metallic luster.

That is, a touch panel manufacturing method of a first aspect of the present invention is a method for manufacturing a touch panel including a transparent substrate having a main surface on which a transparent-electroconductive film is formed. In the method, the transparent-electroconductive film is formed on the main surface of the transparent substrate by carrying out sputtering using a target made of a zinc oxide-based material in a reactive gas atmosphere containing two or three gases selected from a group consisting of hydrogen gas, oxygen gas, and water vapor.

Here, the touch panel of the present invention includes a resistance film type in which a pair of transparent substrates on which a transparent-electroconductive film is formed are arranged to be opposite to each other at a predetermined gap such that the transparent-electroconductive films are opposite to each other, and the position where the pair of transparent-electroconductive films are in contact each other is detected.

The touch panel of the present invention may be a capacitance type in which a low-pressure electric field is formed over the entire surface of the touch panel and in which, when the user touches a portion to be depressed, the electric field is discharged, and the position is detected.

In this manufacturing method, sputtering is carried out using the target made of the zinc oxide-based material in the reactive gas atmosphere containing two or three gases selected from the group consisting of the hydrogen gas, the oxygen gas, and the water vapor so as to form the transparent-electroconductive film on the main surface of the transparent substrate.

Thus, the atmosphere when the zinc oxide-based transparent-electroconductive film is formed on the transparent substrate by sputtering can be set as the atmosphere containing two or three gases selected from the group consisting of the hydrogen gas, the oxygen gas, and water vapor, that is, an atmosphere in which the ratio of a reductive gas to an oxidative gas is balanced.

Therefore, if sputtering is carried out in this atmosphere, the number of oxygen vacancies is controlled in the zinc oxide crystal of the resultant transparent-electroconductive film, and a transparent-electroconductive film having a desired conductivity is realized.

Additionally, the specific resistance of the transparent-electroconductive film is decreased, a transparent-electroconductive film having a desired specific resistance value is realized.

The resultant transparent-electroconductive film can maintain the transparency thereof to visible light beams without causing metallic luster.

A touch panel manufacturing method of a second aspect of the present invention is a method for manufacturing a touch panel including a first transparent substrate and a second transparent substrate having a main surface on which a transparent-electroconductive film is formed, the first transparent substrate and the second transparent substrate being arranged to face each other at a predetermined gap so that a transparent-electroconductive film of the first transparent substrate and the transparent-electroconductive film of the second transparent substrate are arranged to face each other and separated from each other by a predetermined gap. In the method, the transparent-electroconductive film is formed on the main surface of one or both of the first transparent substrate and the second transparent substrate by carrying out sputtering using a target made of a zinc oxide-based material in a reactive gas atmosphere containing two or three gases selected from a group consisting of hydrogen gas, oxygen gas, and water vapor.

In this manufacturing method, sputtering is carried out using a target made of a zinc oxide-based material in the reactive gas atmosphere containing two or three gases selected from the group consisting of the hydrogen gas, the oxygen gas, and the water vapor so as to form the transparent-electroconductive film on the main surface of one or both of the pair of the first transparent substrate and the second transparent substrate.

Thus, the atmosphere when the zinc oxide-based transparent-electroconductive film is formed on the transparent substrate by sputtering can be set to the atmosphere containing two or three gases selected from the group consisting of the hydrogen gas, the oxygen gas, and water vapor, that is, an atmosphere in which the ratio of a reductive gas to an oxidative gas is balanced.

Therefore, if sputtering is carried out in this atmosphere, the number of oxygen vacancies is controlled in the zinc oxide crystal of the resultant transparent-electroconductive film, a transparent-electroconductive film having a desired conductivity is realized.

Additionally, the specific resistance of the transparent-electroconductive film decreases, a transparent-electroconductive film having a desired specific resistance value is realized.

The resultant transparent-electroconductive film can maintain the transparency thereof to visible light beams without causing metallic luster.

A touch panel manufacturing method of a third aspect of the present invention is a method for manufacturing a touch panel including a first transparent substrate and a second transparent substrate having a main surface on which a transparent-electroconductive film is formed, the first transparent substrate and the second transparent substrate being arranged to face each other at a predetermined gap so that a transparent-electroconductive film of the first transparent substrate and the transparent-electroconductive film of the second transparent substrate are arranged to face each other and separated from each other by a predetermined gap. In the method, an optical film is formed on the main surface of one of the first transparent substrate and the second transparent substrate by carrying out sputtering using a target made of a zinc oxide-based material in a reactive gas atmosphere containing two or three gases selected from a group consisting of hydrogen gas, oxygen gas, and water vapor; and the transparent-electroconductive film is subsequently formed on the optical film.

In this manufacturing method, sputtering is carried out using a target made of a zinc oxide-based material in the reactive gas atmosphere containing two or three gases selected from the group consisting of the hydrogen gas, the oxygen gas, and the water vapor so as to form the optical film on the main surface of one of the pair of the first transparent substrate and the second transparent substrate.

Thus, the atmosphere when the zinc oxide-based optical film is formed on the transparent substrate by sputtering can be set to the atmosphere containing two or three gases selected from the group consisting of the hydrogen gas, the oxygen gas, and water vapor, that is, an atmosphere in which the ratio of a reductive gas to an oxidative gas is balanced.

Therefore, if sputtering is carried out in this atmosphere, the number of oxygen vacancies is controlled in the zinc oxide crystal of the resultant optical film, and light absorption due to the oxygen vacancies decreases. As a result, it is possible to maintain the transparency thereof to visible light beams without causing metallic luster.

A touch panel manufacturing method of a fourth aspect of the present invention is a method for manufacturing a touch panel including a first transparent substrate and a second transparent substrate having a main surface on which a transparent-electroconductive film is formed, the first transparent substrate and the second transparent substrate being arranged to face each other at a predetermined gap so that a transparent-electroconductive film of the first transparent substrate and the transparent-electroconductive film of the second transparent substrate are arranged to face each other and separated from each other by a predetermined gap. In the method, an optical film is formed on the main surface of one of the first transparent substrate and the second transparent substrate by carrying out sputtering using a target made of a first zinc oxide-based material in a reactive gas atmosphere containing two or three gases selected from a group consisting of hydrogen gas, oxygen gas, and water vapor; and the transparent-electroconductive film is subsequently formed on the optical film by carrying out sputtering using a target made of a second zinc oxide-based material in a reactive gas atmosphere containing two or three gases selected from a group consisting of hydrogen gas, oxygen gas, and water vapor.

In this manufacturing method, sputtering is carried out using a target made of a first zinc oxide-based material in the reactive gas atmosphere containing two or three gases selected from the group consisting of the hydrogen gas, the oxygen gas, and the water vapor so as to form the optical film on the main surface of one of the pair of the first transparent substrate and the second transparent substrate.

Thus, the atmosphere when the zinc oxide-based optical film is formed on the transparent substrate by sputtering can be set to the atmosphere containing two or three gases selected from the group consisting of the hydrogen gas, the oxygen gas, and water vapor, that is, an atmosphere in which the ratio of a reductive gas to an oxidative gas is balanced.

Therefore, if sputtering is carried out in this atmosphere, the number of oxygen vacancies is controlled in the zinc oxide crystal of the resultant optical film, and light absorption due to the oxygen vacancies decreases. As a result, it is possible to maintain the transparency thereof to visible light beams without causing metallic luster.

Sputtering is carried out using a target made of a second zinc oxide-based material in the reactive gas atmosphere containing two or three gases selected from the group consisting of the hydrogen gas, the oxygen gas, and the water vapor so as to form the transparent-electroconductive film on the optical film.

Thus, the atmosphere when the zinc oxide-based transparent-electroconductive film is formed on the optical film by sputtering can be set to the atmosphere containing two or three gases selected from the group consisting of the hydrogen gas, the oxygen gas, and water vapor, that is, an atmosphere in which the ratio of a reductive gas to an oxidative gas is balanced.

Therefore, if sputtering is carried out in this atmosphere, the number of oxygen vacancies is controlled in the zinc oxide crystal of the resultant transparent-electroconductive film, a transparent-electroconductive film having a desired conductivity is realized.

The specific resistance of the transparent-electroconductive film decreases, a transparent-electroconductive film having a desired specific resistance value is realized.

The resultant transparent-electroconductive film can maintain the transparency thereof to visible light beams without causing metallic luster.

In the manufacturing method of the first to fourth aspects of the present invention, it is preferable that the ratio R(P_{H2}/P_{O2}) of a partial pressure (P_{H2}) of the hydrogen gas to a partial pressure (P_{O2}) of the oxygen gas satisfy the following expression (1).

R=P_{H2}/P_{O2}≧5 (1)

In the manufacturing method of the first to fourth aspects of the present invention, it is preferable that a sputtering voltage when the sputtering is carried out be less than or equal to 340 V.

In the manufacturing method of the first to fourth aspects of the present invention, it is preferable that the sputtering voltage when the sputtering is carried out be a voltage in which a high-frequency voltage is superimposed on a direct-current voltage.

In the manufacturing method of the first to fourth aspects of the present invention, it is preferable that the maximum value of the intensity of the horizontal magnetic field on a surface of the target be greater than or equal to 600 gauss.

In the manufacturing method of the first to fourth aspects of the present invention, it is preferable that the zinc oxide-based material be aluminum-added zinc oxide or gallium-added zinc oxide.

A film formation apparatus of a fifth aspect of the present invention which manufactures a touch panel, includes: a vacuum chamber; a target holding section holding a target in the vacuum chamber; and a power source applying a sputtering voltage to the target. The vacuum chamber has two or more of a hydrogen gas introduction section, an oxygen gas introduction section, and a water vapor introduction section.

In this film formation apparatus, the vacuum chamber includes two or more of the hydrogen gas introduction section, the oxygen gas introduction section, and the water vapor introduction section.

Thus, by using two or more of the hydrogen gas introduction section, the oxygen gas introduction section, and the water vapor introduction section, the atmosphere when a zinc oxide-based transparent-electroconductive film or an optical film is formed on the substrate by sputtering using a target made of a zinc oxide-based material can be set to the reactive gas atmosphere in which the ratio of a reductive gas to an oxidative gas is balanced.

Therefore, by a single apparatus using a target made of a zinc oxide-based material, it is possible to form one or both of a zinc oxide-based transparent-electroconductive film which can maintain the transparency thereof to visible light beams without causing metallic luster and in which the number of oxygen vacancies are controlled in the zinc oxide crystal and it is thereby possible to decrease the specific resistance, and a zinc oxide-based optical film which can maintain the transparency thereof to visible light beams without causing metallic luster.

Furthermore, in this film formation apparatus, it is possible to form not only the transparent-electroconductive film or the optical film, but also a multilayered optical film or a multilayered optical film and a transparent-electroconductive film simply by using one type of target made of a zinc oxide-based material and by changing the gas to be introduced.

Moreover, it is possible to use a DC power source or an AC power source and to form a film as fast as or faster than the conventional film formation rate.

In the manufacturing method of the fifth aspect of the present invention, it is preferable that the power source use both a direct-current power source and a high-frequency power source.

In this film formation apparatus, by using both a direct-current power source and a high-frequency power source, it is possible to decrease a sputtering voltage and to form the zinc oxide-based transparent-electroconductive film or the optical film with arranged crystal lattices.

With this film formation apparatus, it is possible to obtain a transparent-electroconductive film having low specific resistance and capable of maintaining transparency to visible light beams without causing metallic luster.

It is possible to obtain an optical film capable of maintaining transparency to visible light beams without causing metallic luster.

It is preferable that the manufacturing method of the fifth aspect of the present invention include a magnetic field generation section provided in the target holding section, generating a horizontal magnetic field having a maximum intensity value greater than or equal to 600 gauss on a surface of the target.

In this film formation apparatus, the magnetic field generation section is provided in the target holding section to generate a horizontal magnetic field having a maximum intensity value greater than or equal to 600 gauss on the surface of the target. For this reason, high-density plasma is generated at a position where a vertical magnetic field on the surface of the target becomes 0 (a horizontal magnetic field is maximized).

Therefore, it is possible to form a zinc oxide-based transparent-electroconductive film or the optical film with arranged crystal lattices.

### ADVANTAGEOUS EFFECTS OF INVENTION

According to the touch panel manufacturing method of the first aspect of the present invention, sputtering is carried out using a target made of a zinc oxide-based material in the reactive gas atmosphere containing two or three gases selected from the group consisting of the hydrogen gas, the oxygen gas, and the water vapor so as to form the transparent-electroconductive film on the main surface of the transparent substrate. Thus, it is possible to decrease the specific resistance of the zinc oxide-based transparent-electroconductive film and to maintain the transparency thereof to visible light beams.

Therefore, it is possible to easily form a zinc oxide-based transparent-electroconductive film having low specific resistance and excellent transparency thereof to visible light beams.

According to the touch panel manufacturing method of the second aspect of the present invention, sputtering is carried out using a target made of a zinc oxide-based material in the reactive gas atmosphere containing two or three gases selected from the group consisting of the hydrogen gas, the oxygen gas, and the water vapor so as to form the transparent-electroconductive film on the main surface of one or both of the pair of the first transparent substrate and the second transparent substrate. Thus, it is possible to decrease the specific resistance of the zinc oxide-based transparent-electroconductive film and to maintain the transparency thereof to visible light beams.

Therefore, it is possible to easily form a zinc oxide-based transparent-electroconductive film having low specific resistance and excellent transparency thereof to visible light beams.

According to the touch panel manufacturing method of the third aspect of the present invention, sputtering is carried out using a target made of a zinc oxide-based material in the reactive gas atmosphere containing two or three gases selected from the group consisting of the hydrogen gas, the oxygen gas, and the water vapor so as to form the optical film on the main surface of one of the pair of the first transparent substrate and the second transparent substrate. Thus, it is possible to prevent metallic luster in the zinc oxide-based optical film and to maintain the transparency thereof to visible light beams.

Therefore, it is possible to easily form a zinc oxide-based optical film having excellent transparency thereof to visible light beams.

According to the touch panel manufacturing method of the fourth aspect of the present invention, sputtering is carried out using a target made of a first zinc oxide-based material in the reactive gas atmosphere containing two or three gases selected from the group consisting of the hydrogen gas, the oxygen gas, and the water vapor so as to form the optical film on the main surface of one of the pair of the first transparent substrate and the second transparent substrate. Thus, it is possible to prevent metallic luster in the zinc oxide-based optical film and to maintain the transparency thereof to visible light beams.

Therefore, it is possible to easily form a zinc oxide-based optical film having excellent transparency thereof to visible light beams.

Sputtering is carried out using a target made of a second zinc oxide-based material in the reactive gas atmosphere containing two or three gases selected from the group consisting of the hydrogen gas, the oxygen gas, and the water vapor so as to form the transparent-electroconductive film on the optical film. Thus, it is possible to decrease the specific resistance of the zinc oxide-based transparent-electroconductive film and to maintain the transparency thereof to visible light beams.

Therefore, it is possible to easily form a zinc oxide-based transparent-electroconductive film having low specific resistance and excellent transparency thereof to visible light beams.

With the film formation apparatus for manufacturing a touch panel according to the fifth aspect of the present invention, a vacuum chamber includes two or more of a hydrogen gas introduction section, an oxygen gas introduction section, and a water vapor introduction section. Thus, if these portions are controlled, the atmosphere when a zinc oxide-based transparent-electroconductive film or the optical film is formed inside the vacuum chamber can be set to the reactive gas atmosphere in which the ratio of a reductive gas to an oxidative gas is balanced.

Therefore, with the improvement of a part of a conventional film formation apparatus, it is possible to easily form a zinc oxide-based transparent-electroconductive film having low specific resistance and excellent transparency thereof to visible light beams or a zinc oxide-based optical film having excellent transparency thereof to visible light beams, using a single apparatus using a target made of a zinc oxide-based material.

In addition to the transparent-electroconductive film or the optical film, it is possible to form a multilayered optical film or a multilayered optical film and a transparent-electroconductive film simply by using one type of target made of a zinc oxide-based material and by changing the gas to be introduced.

It is possible to use a DC power source or an AC power source and to form a film as fast as or faster than the conventional film formation rate.

### BRIEF DESCRIPTION OF THE DRAWINGS

FIG. 1 is a sectional view showing a main part of a resistance film type touch panel according to a first embodiment of the present invention.

FIG. 2 is a sectional view showing an anti-reflective film of the resistance film type touch panel according to the first embodiment of the present invention.

FIG. 3 is a schematic configuration diagram showing a sputtering apparatus according to the first embodiment of the present invention.

FIG. 4 is a sectional view showing a main part of a film formation chamber of the sputtering apparatus according to the first embodiment of the present invention.

FIG. 5 is a diagram showing the effect of H₂O gas (water vapor) at the time of non-heating film formation.

FIG. 6 is a diagram showing the simulation result of reflectance of the anti-reflective film.

FIG. 7 is a diagram showing the effect of H₂O gas (water vapor) at the time of heating film formation when the substrate temperature is set to 250° C.

FIG. 8 is a diagram showing the effect of simultaneous introduction of H₂ gas and O₂ gas at the time of heating film formation when a substrate temperature is set to 250° C.

FIG. 9 is a diagram showing the effect of simultaneous introduction of H₂ gas and O₂ gas at the time of heating film formation when the substrate temperature is set to 250° C.

FIG. 10 is a diagram showing the effect of H₂ gas at the time of non-heating film formation.

FIG. 11 is a sectional view showing a main part of a film formation chamber in an interback magnetron sputtering apparatus according to a second embodiment of the present invention.

### DESCRIPTION OF THE PREFERRED EMBODIMENTS

The best mode for carrying out a touch panel manufacturing method and a film formation apparatus of the present invention will be described.

Although in this embodiment, specific description will be provided for ease of understanding of the scope of the present invention, this embodiment is not intended to limit the technical scope of the present invention, and various alterations may be made without departing from the scope of the present invention.

### First Embodiment

Touch Panel

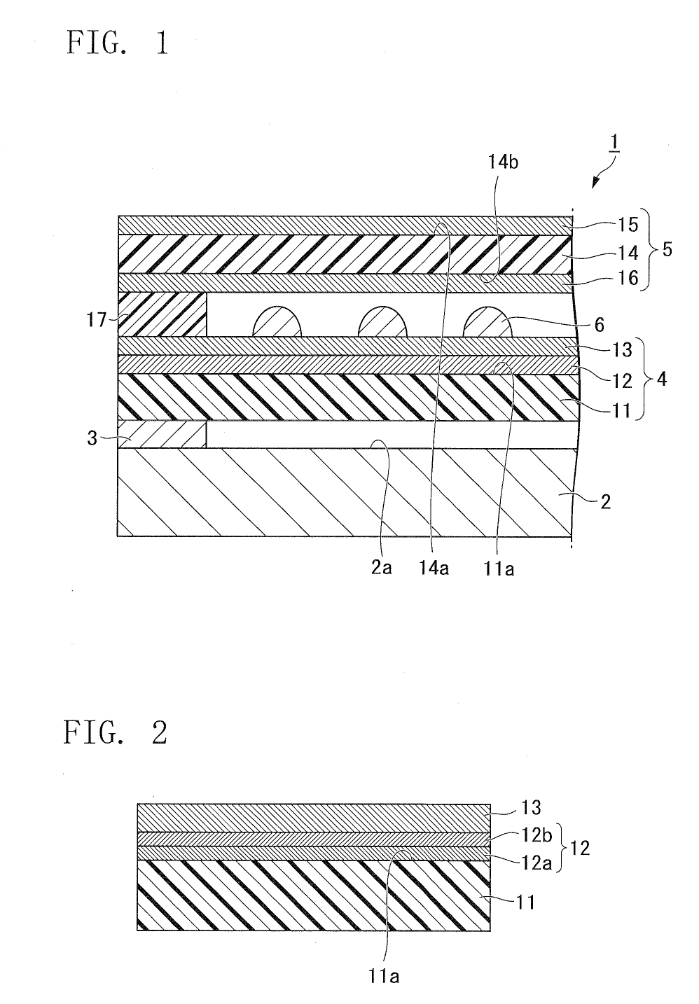

FIG. 1 is a sectional view showing a main part of a resistance film type touch panel according to a first embodiment of the present invention.

A touch panel 1 is provided on an image display surface 2a of a liquid crystal display (LCD) 2 with spacers 3 interposed therebetween, and includes a drive circuit 4 serving as a lower electrode, a detection circuit 5 serving as an upper electrode, and a plurality of insulating spacers 6 disposed between the drive circuit 4 and the detection circuit 5.

The drive circuit 4 is configured such that an anti-reflective film (optical film) 12 and a transparent-electroconductive film 13 are sequentially formed on a front surface (main surface) 11a of a transparent substrate 11 made of plastic, such as a polyimide film, or a glass plate made of alkali-free glass.

The detection circuit 5 is configured such that a hard coat film 15 is formed on a front surface 14a of a plastic film (transparent substrate) 14 made of polyethylene terephthalate (PET) or the like, and a transparent-electroconductive film 16 is formed on a rear surface (main surface) 14b of the plastic film 14.

The drive circuit 4 and the detection circuit 5 are disposed at a predetermined gap such that the transparent-electroconductive films 13 and 16 are opposite to each other.

The transparent-electroconductive films 13 and 16 are adhered and fixed via an adhesive 17, and a plurality of spacers 6 are disposed in a matrix between the transparent-electroconductive films 13 and 16 so as to maintain the distance between the transparent-electroconductive films 13 and 16.

As shown in FIG. 2, the anti-reflective film 12 has a layered structure in which a plurality of transparent films having different refractive indexes, for example, a high-refractive-index transparent film 12a and a low-refractive-index transparent film 12b are superimposed on each other, such that the refractive index sequentially decreases from the front surface 11a of the transparent substrate 11 toward the position where the transparent-electroconductive film 13 is disposed.

As the layered structure of the anti-reflective film 12, for example, a layered structure is suitably used in which films mainly containing aluminum-added zinc oxide (AZO) added with aluminum oxide (Al₂O₃), gallium-added zinc oxide (GZO) added with gallium oxide (Ga₂O₃), silicon oxide (SiO₂), titanium oxide (TiO₂), or the like are laminated.

For example, in the case of a layered structure using aluminum-added zinc oxide (AZO), the high-refractive-index transparent film 12a having a refractive index of, for example, 1.91 or the like, is obtained through film formation in an argon (Ar) gas atmosphere or an oxygen-containing argon (Ar+O₂) gas atmosphere with aluminum-added zinc oxide (AZO) as a target.

The low-refractive-index transparent film 12b having a refractive index of, for example, 1.64 or the like, is obtained through film formation in a hydrogen (H₂) gas atmosphere or a water vapor (H₂O) atmosphere with aluminum-added zinc oxide (AZO) as a target.

As described above, it is possible to form films having two types of refractive indexes using the same type of target simply by changing the type of reactive gas.

Therefore, it is possible to easily form a film having a layered structure by a single apparatus (same apparatus).

When a ZnO-based target, such as AZO or GZO, is used, it is possible to carry out sputtering only with a DC power source or an AC power source, simplifying the structure of the film formation apparatus.

Although RF sputtering is carried out at a relatively low film formation rate, in the film formation apparatus of the first embodiment, since a DC power source or an AC power source can be used, it is possible to also increase the film formation rate.

If the RF output is superimposed on the output of the DC power source or the AC power source, it is possible to decrease electric discharge pressure.

When a DC power source is used, for example, in the case of reactive sputtering using a conventional Si target, the film formation rate is 20 to 30 Å/minute (for 1 W/cm²: the same is applied to the following description), and in the case of reactive sputtering using Ti, the film formation rate is substantially A/minute. Meanwhile, in sputtering an AZO film with ZnO—Al₂O₃ as a target, the film formation rate of 50 to 80 Å/minute is obtained.

Furthermore, in sputtering an AZO film with ZnO—Al₂O₃ as a target while introducing gas including oxygen or hydrogen atoms, since the target contains oxygen, the amount of reactive gas to be introduced is small compared to reactive sputtering using a target of Si or Ti.

In the touch panel 1, a desired position (address) on the hard coat film 15 of the plastic film 14 is depressed toward the transparent substrate 11 with a touch pen or a finger, such that the transparent-electroconductive film 13 and the transparent-electroconductive film 16 are electrically connected to each other (electrical conduction is provided therebetween) at the desired position (address), and the “ON” state is reached. Then, information regarding the “ON” state at the desired position (address) is output as an electrical signal representing the manipulated address within the surface of the touch panel 1.

Sputtering Apparatus

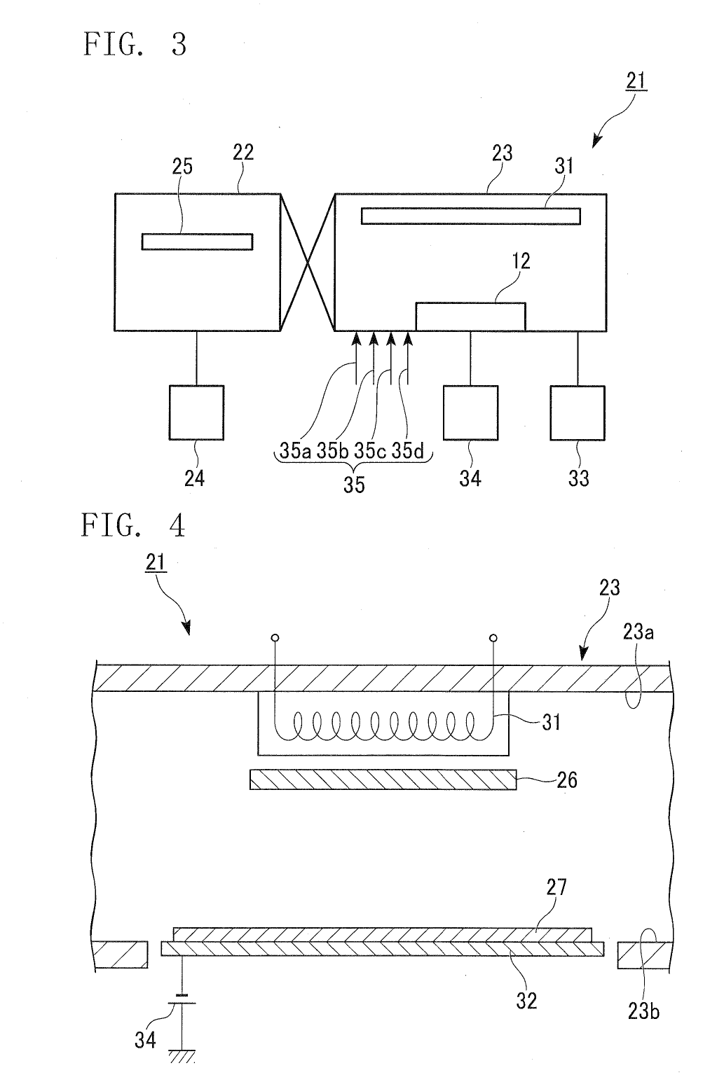

FIG. 3 is a schematic configuration diagram of a sputtering apparatus (film formation apparatus) which is used in the touch panel manufacturing method of the first embodiment. FIG. 4 is a sectional view showing a main part of a film formation chamber in the sputtering apparatus of FIG. 3.

A sputtering apparatus 21 is an interback sputtering apparatus, and includes, for example, a load/unload chamber 22 which loads or unloads a substrate, such as an alkali-free glass substrate (not shown), and a film formation chamber (vacuum chamber) 23 in which a zinc oxide-based transparent-electroconductive film is formed on the substrate.

The load/unload chamber 22 is provided with a rough-vacuuming section 24, such as a rotary pump, which roughly vacuumizes the chamber. A substrate tray 25 is movably disposed in the chamber to hold and transport the substrate.

On the other hand, a heater 31 is vertically provided at one lateral surface (first lateral surface) 23a of the film formation chamber 23 to heat a substrate 26, and a cathode (target holding section) 32 is vertically provided at the other lateral surface (second lateral surface) 23b to hold a target 27 made of a zinc oxide-based material and to apply a desired sputtering voltage. At the other lateral surface 23b, a high-vacuuming section 33, such as a turbo-molecular pump, which highly vacuumizes the chamber, a power source 34 which applies a sputtering voltage to the target 27, and a gas introduction section 35 which introduces gas into the chamber are also provided.

The cathode 32 is a member which is formed of a plate-shaped metal plate and to which the target 27 is bonded (fixed) via a soldering material or the like.

The power source 34 has a function of applying a sputtering voltage in which a high-frequency voltage is superimposed on a direct-current voltage to the target 27, and includes a direct-current (DC) power source and a high-frequency (RF) power source (not shown).

The gas introduction section 35 includes a sputtering gas introduction section 35a which introduces a sputtering gas, such as Ar, a hydrogen gas introduction section 35b which introduces hydrogen gas, an oxygen gas introduction section 35c which introduces oxygen gas, and a water vapor introduction section 35d which introduces water vapor.

In the gas introduction section 35, the introduction sections 35b to 35d are selectively used as necessary. The gas introduction section 35 may include, for example, two introduction sections of the hydrogen gas introduction section 35b and the oxygen gas introduction section 35c, or two introduction sections of the hydrogen gas introduction section 35b and the water vapor introduction section 35d.

Next, a method will be described which sequentially forms the zinc oxide-based anti-reflective film 12 and the transparent-electroconductive film 13 on the transparent substrate 11 by using the above-described sputtering apparatus 21.

Here, a case will be described where an alkali-free glass substrate is used as the transparent substrate 11, and a two-layered film made of a zinc oxide-based material, such as aluminum-added zinc oxide (AZO) or gallium-added zinc oxide (GZO), is used as the anti-reflective film 12.

Formation of Anti-Reflective Film

(a) Formation of High-Refractive-Index Transparent Film

In order to form the high-refractive-index transparent film 12a, the zinc oxide-based target 27 is bonded and fixed to the cathode 32 with a soldering material or the like.

Here, examples of the target material include zinc oxide-based materials, for example, aluminum-added zinc oxide (AZO) added with 0.1 to 10% by mass of aluminum oxide (Al₂O₃), gallium-added zinc oxide (GZO) added with 0.1 to 10% by mass of gallium oxide (Ga₂O₃), and the like.

Next, the load/unload chamber 22 and the film formation chamber 23 are roughly vacuumized by the rough-vacuuming section 24 in a state where the substrate 26 is accommodated in the substrate tray 25 of the load/unload chamber 22.

After the load/unload chamber 22 and the film formation chamber 23 are at a predetermined degree of vacuum, for example, 0.27 Pa (2.0×10⁻³ Torr), the substrate 26 is loaded from the load/unload chamber 22 into the film formation chamber 23.

The substrate 26 is disposed in front of the heater 31 which is in a state where the setting is off, the substrate 26 is opposite to the target 27, and the substrate 26 is heated by the heater 31 to bring the temperature in a range of 100° C. to 600° C.

Next, the film formation chamber 23 is highly vacuumized by the high-vacuuming section 33, such that the film formation chamber 23 is set at a predetermined high degree of vacuum, for example, 2.7×10⁻⁴ Pa (2.0×10⁻⁶ Torr).

Thereafter, the sputtering gas introduction section 35a introduces Ar gas into the film formation chamber 23, or the sputtering gas introduction section 35a and the oxygen gas introduction section 35c introduce Ar gas and O₂ gas into the film formation chamber 23, such that the film formation chamber 23 is in an Ar gas atmosphere or an O₂ gas-containing Ar gas (Ar+O₂) atmosphere.

Next, a sputtering voltage is applied from the power source 34 to the target 27.

The sputtering voltage is preferably less than or equal to 340 V.

A decrease in a discharge voltage makes it possible to form a zinc oxide-based transparent film with arranged crystal lattices.

The sputtering voltage is preferably a voltage in which a high-frequency voltage is superimposed on a direct-current voltage.

Superimposition of the high-frequency voltage on a direct-current voltage makes it possible to further decrease the electric discharge voltage.

Due to applying the sputtering voltage, plasma is generated on the substrate 26, the ions of sputtering gas, such as Ar, excited by plasma collide against the target 27, and atoms constituting a zinc oxide-based material, such as aluminum-added zinc oxide (AZO) or gallium-added zinc oxide (GZO), are emitted from the target 27. Thus, a transparent film made of a zinc oxide-based material is formed on the substrate 26.

In the course of the film formation, the atmosphere of the film formation chamber 23 is an Ar gas atmosphere or an O₂ gas-containing Ar gas (Ar+O₂) atmosphere. For this reason, if sputtering is carried out in this atmosphere, the number of oxygen vacancies is controlled in the zinc oxide crystal of the resultant transparent film, obtaining the high-refractive-index transparent film 12a having a desired high refractive index, for example, approximately 2.0 and desired specific resistance (conductivity).

When the refractive index of the transparent film 12a is shifted, that is, when the value of the refractive index of the transparent film 12a is adjusted in accordance with the refractive index characteristic, the atmosphere at the time of film formation is preferably changed from the Ar gas atmosphere or the O₂ gas-containing Ar gas (Ar+O₂) atmosphere to an atmosphere in which H₂ gas and/or H₂O gas (water vapor) is added to Ar gas or O₂ gas-containing Ar gas.

This can be realized by performing one or both of introduction of H₂ gas into the film formation chamber 23 by the hydrogen gas introduction section 35b or introduction of H₂O gas (water vapor) into the film formation chamber 23 by the water vapor introduction section 35d.

(b) Formation of Low-Refractive-Index Transparent Film

In a state where the zinc oxide-based target 27 is left in the film formation chamber 23, the atmosphere of the film formation chamber 23 is controlled so as to contain H₂ gas and/or H₂O gas (water vapor) by performing one or both of introduction of H₂ gas into the film formation chamber 23 by the hydrogen gas introduction section 35b and introduction of H₂O gas (water vapor) into the film formation chamber 23 by the water vapor introduction section 35d.

In forming the low-refractive-index transparent film, the atmosphere at the time of film formation is controlled so as to contain H₂ gas and/or H₂O gas (water vapor) by using the same zinc oxide-based target 27 as in the forming of the high-refractive-index transparent film.

Thus, the low-refractive-index transparent film is formed such that the refractive index of the transparent film is shifted to the low refractive index side.

Here, H₂ gas and/or H₂O gas (water vapor) are introduced into the film formation chamber 23 by using the hydrogen gas introduction section 35b or the water vapor introduction section 35d.

Ar gas or O₂ gas-containing Ar gas (Ar+O₂) is included in the film formation chamber 23. For this reason, the partial pressure of each of H₂ gas, H₂O gas (water vapor), and Ar+O₂ gas is controlled, and it is thereby possible to control the refractive index or the specific resistance (conductivity) of the resultant transparent film.

For example, when the ratio R(P_{H2}/P_{O2}) of the partial pressure (P_{H2}) of hydrogen gas to the partial pressure (P_{O2}) of oxygen gas satisfies the following expression (1), the atmosphere of the film formation chamber 23 is controlled so as to contain reactive gas having a hydrogen gas concentration greater than or equal to five times the oxygen gas concentration.

R=P_{H2}/P_{O2}≧5 (1)

If the reactive gas atmosphere satisfies R=P_{H2}/P_{O2}≧5, the transparent film 12b having a refractive index of approximately 1.6 is obtained.

When the ratio R(P_{H2}/P_{H2O}) of the partial pressure (P_{H2}) of the hydrogen gas to the partial pressure (P_{H2O}) of water vapor (gas) satisfies the following expression (2), the atmosphere of the film formation chamber 23 is controlled so as to contain reactive gas having a hydrogen gas concentration greater than or equal to five times the water vapor concentration.

R=P_{H2}/P_{H2O}≧5 (2)

If the reactive gas atmosphere satisfies R=P_{H2}/P_{H2O}≧5, the transparent film 12b having a refractive index of approximately 1.6 is obtained.

As described above, the H₂ gas and/or H₂O gas (water vapor) atmosphere is formed in the film formation chamber 23, such that the specific resistance (conductivity) of the resultant transparent film 12b is also changed.

Thus, in forming the transparent film 12b which requires conductivity, it is necessary to form the film in the H₂ gas atmosphere.

Meanwhile, in forming the transparent film 12b which does not require conductivity, either the H₂ gas atmosphere or the H₂O gas (water vapor) atmosphere is used.

As described above, the low-refractive-index transparent film 12b which is formed in the H₂ gas and H₂O gas (H₂+H₂O) atmosphere has low specific resistance, and can be thus used as a transparent-electroconductive film.

Therefore, the transparent-electroconductive film 13 is not required.

Meanwhile, the low-refractive-index transparent film 12b which is formed in the H₂O gas atmosphere has high specific resistance, thus, the transparent-electroconductive film 13 is required.

Next, a method will be described which forms the transparent-electroconductive film 13 on the transparent film 12b having high specific resistance and a low refractive index.

Formation of Transparent-Electroconductive Film

In forming the transparent-electroconductive film 13, the zinc oxide-based target 27 is used, and in the same manner as in the method of forming the anti-reflective film, the temperature of the substrate 26 is in a range of 100° C. to 600° C.

A sputtering gas, such as Ar, is introduced by the sputtering gas introduction section 15a, and two or three gases selected from the group consisting of hydrogen gas, oxygen gas, and water vapor are introduced by two or three introduction sections of the hydrogen gas introduction section 15b to the water vapor introduction section 15d.

Here, when the hydrogen gas and the oxygen gas are selected, when the ratio R (P_{H2}/P_{O2}) of the partial pressure (P_{H2}) of the hydrogen gas to the partial pressure (P_{O2}) of the oxygen gas satisfies the following expression (3), the atmosphere of the film formation chamber 23 is controlled so as to contain reactive gas having the hydrogen gas concentration greater than or equal to five times the oxygen gas concentration.

R=P_{H2}/P_{O2}≧5 (3)

If the reactive gas atmosphere satisfies R=P_{H2}/P_{O2}≧5, the transparent-electroconductive film having a specific resistance less than or equal to 1.0×10³ μΩ·cm is obtained.

When the hydrogen gas and water vapor (gas) are selected, if the ratio R(P_{H2}/P_{H2O}) of the partial pressure (P_{H2}) of the hydrogen gas to the partial pressure (P_{H2O}) of water vapor (gas) satisfies the following expression (4), the atmosphere of the film formation chamber 23 is controlled so as to contain a reactive gas having a hydrogen gas concentration greater than or equal to five times the water vapor concentration.

R=P_{H2}/P_{H2O}≧5 (4)

If the reactive gas atmosphere satisfies R=P_{H2}/P_{H2O}≧5, the transparent-electroconductive film having a specific resistance less than or equal to 1.0×10³ μΩ·cm is obtained.

Next, a sputtering voltage less than or equal to 340 V, preferably, a sputtering voltage in which a high-frequency voltage is superimposed on a direct-current voltage is applied from the power source 34 to the target 27.

Accordingly, plasma is generated on the substrate 26, ions of the sputtering gas, such as Ar, excited by plasma collide against the target 27, and atoms constituting a zinc oxide-based material, such as aluminum-added zinc oxide (AZO) or gallium-added zinc oxide (GZO) are emitted from the target 27. Thus, the transparent-electroconductive film made of a zinc oxide-based material is formed on the transparent film 12b.

In the course of the film formation, the atmosphere of the film formation chamber 23 is a reactive gas atmosphere which is made of two or three gases selected from the group constituting of the hydrogen gas, the oxygen gas, and the water vapor.

Therefore, if sputtering is carried out in the reactive gas atmosphere, the number of oxygen vacancies is controlled in the zinc oxide crystal, the resultant transparent-electroconductive film becomes a film having a desired conductivity, and the specific resistance of the transparent-electroconductive film decreases, obtaining a desired specific resistance value.

In particular, with regard to the concentration of each gas in the film formation chamber 23, when the hydrogen gas concentration is greater than or equal to five times the oxygen gas concentration, a reactive gas atmosphere is obtained in which the ratio of a hydrogen gas to an oxygen gas is balanced.

Thus, if sputtering is carried out in this reactive gas atmosphere, the number of oxygen vacancies is highly controlled in the zinc oxide crystal, the resultant transparent-electroconductive film becomes a film having a desired conductivity, and the specific resistance of the transparent-electroconductive film decreases to a value corresponding to an ITO film, obtaining a desired specific resistance value.

In the resultant transparent-electroconductive film, transparency to visible light beams is maintained without causing metallic luster.

In this way, the substrate 26 is obtained on which the zinc oxide-based transparent-electroconductive film 13 having low specific resistance and good transparency to visible light beams is formed.

Next, with regard to the method of manufacturing a zinc oxide-based transparent-electroconductive film and an anti-reflective film of the first embodiment, the result of an experiment by the inventors will be described.

An aluminum-added zinc oxide (AZO) target was prepared which has a size of 5 inches×16 inches and has been added with 2% by mass of Al₂O₃.

The target was fixed to the parallel flat plate-shaped cathode 32, which applies a direct-current (DC) voltage thereto, with a soldering material.

Next, an alkali-free glass substrate was loaded into the load/unload chamber 22, and the load/unload chamber 22 was roughly vacuumized by the rough-vacuuming section 24. Next, the alkali-free glass substrate was loaded into the film formation chamber 23 which has been highly vacuumized by the high-vacuuming section 33.

Thereafter, the alkali-free glass substrate was disposed to be opposite the AZO target.

Next, the pressure of the film formation chamber 23 was controlled so as to be 5 mTorr while introducing Ar gas into the film formation chamber 23 by the gas introduction section 35.

Thereafter, gas was introduced into the film formation chamber 23 such that either the partial pressure of H₂O gas becomes 5×10⁻⁵ Torr or the partial pressure of O₂ gas becomes 1×10⁻⁵ Torr, and power of 1 kW was applied from the power source 34 to the cathode 32 in the atmosphere of H₂O gas or O₂ gas.

Thus, the AZO target attached to the cathode 32 was sputtered and an AZO film was deposited on the alkali-free glass substrate.

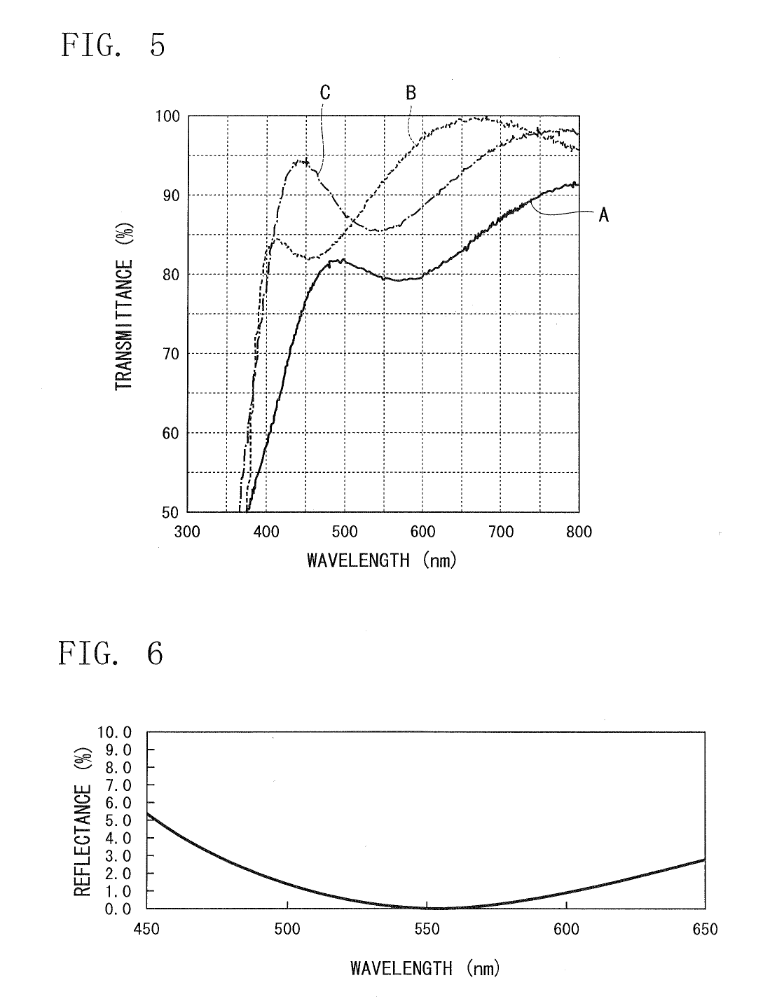

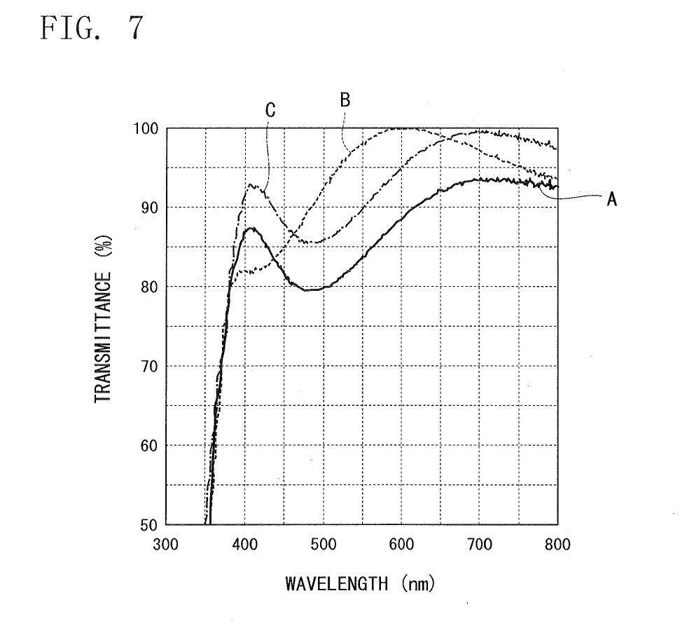

FIG. 5 is a diagram showing the effect of H₂O gas (water vapor) at the time of non-heating film formation.

In FIG. 5, reference numeral A denotes transmittance of the zinc oxide-based transparent-electroconductive film when no reactive gas is introduced, reference numeral B denotes transmittance of the zinc oxide-based transparent-electroconductive film when H₂O gas is introduced at a partial pressure of 5×10⁻⁵ Torr, and reference numeral C denotes transmittance of the zinc oxide-based transparent-electroconductive film when O₂ gas is introduced at a partial pressure of 1×10⁻⁵ Torr.

When no reactive gas is introduced, the film thickness of the transparent-electroconductive film was 207.9 nm, and the specific resistance of the transparent-electroconductive film was 1576 μΩcm.

When H₂O gas is introduced, the film thickness of the transparent-electroconductive film was 204.0 nm, and the specific resistance of the transparent-electroconductive film was 64464 μΩcm.

When O₂ gas is introduced, the film thickness of the transparent-electroconductive film was 208.5 nm, and the specific resistance of the transparent-electroconductive film was 2406 μΩcm.

From FIG. 5, it was seen that, if H₂O gas is introduced, the peak wavelength of transmittance can be changed without changing the film thickness.

Transmittance was increased on the whole compared to the reference numeral A in which no reactive gas is introduced.

It was also seen that, when H₂O gas is introduced, specific resistance is high and resistance degradation increases, but the transmittance is high, and it is thereby applicable to an optical member, such as an anti-reflective film, which does not require low resistance.

It was also seen that, if H₂O gas is repeatedly introduced and stopped or the film formation condition is repeated with the introduction amount of H₂O gas changed, an optical device having a layered structure with a refractive index changed (a layered structure of a plurality of films having different refractive indexes) is obtained using a single target.

FIG. 6 is a diagram showing a simulation result of reflectance of an anti-reflective film when optical design was done using the refractive indexes calculated based on the spectrums of the reference numerals B and C in FIG. 5.

Here, the values of the peak value (λ) of the wavelength of 796 nm and the film thickness (d) of 208.5 nm obtained based on the spectrum of the reference numeral C in FIG. 5 were simply substituted into the expression “2nd=mλ” (in the expression, “d” is the film thickness, “λ” is the wavelength, and “n” and “m” are integers).

When m=1, the refractive index (n) of the high-refractive-index transparent film was calculated to be n=1.91.

On the other hand, the values of the peak value (λ) of the wavelength of 668 nm and the film thickness (d) of 204.0 nm obtained based on the spectrum of the reference numeral B in FIG. 5 were simply substituted into the expression “2nd=mλ” (in expression, d is the film thickness, λ is the wavelength, and n and m are integers).

When m=1, the refractive index (n) of the low-refractive-index transparent film was calculated to be n=1.64.

Next, a high-refractive-index transparent film having a refractive index (n) of 1.91 was formed on the glass substrate so as to have a film thickness (d) of 64.0 nm, and a low-refractive-index transparent film having a refractive index (n) of 1.64 was formed on the high-refractive-index transparent film so as to have a film thickness (d) of 89.5 nm.

According to FIG. 6, it was seen that, when the wavelength (λ) is 550 nm, the reflectance of the anti-reflective film is 0.167%, and the anti-reflective film having a layered structure can be formed continuously by using a single target.

Next, an AZO film was deposited on the alkali-free glass substrate in the same manner as described above, except that the alkali-free glass substrate was heated to 250° C.

FIG. 7 is a diagram showing the effect of H₂O gas (water vapor) at the time of heating film formation when the substrate temperature is at 250° C.

In FIG. 7, reference numeral A denotes transmittance of the zinc oxide-based transparent-electroconductive film when no reactive gas is introduced, reference numeral B denotes transmittance of the zinc oxide-based transparent-electroconductive film when H₂O gas is introduced at a partial pressure of 5×10⁻⁵ Torr, and reference numeral C denotes transmittance of the zinc oxide-based transparent-electroconductive film when O₂ gas is introduced at a partial pressure of 1×10⁻⁵ Torr.

As the cathode, a parallel flat plate-shaped cathode was used which applies a direct-current (DC) voltage.

When no reactive gas is introduced, the film thickness of the transparent-electroconductive film was 201.6 nm, and the specific resistance of the transparent-electroconductive film was 766 μΩcm.

When H₂O gas is introduced, the film thickness of the transparent-electroconductive film was 183.0 nm, and the specific resistance of the transparent-electroconductive film was 6625 μΩcm.

When O₂ gas is introduced, the film thickness of the transparent-electroconductive film was 197.3 nm, and the specific resistance of the transparent-electroconductive film was 2214 μΩcm.

From FIG. 7, it was seen that in the case of heating film formation, the same effects as in non-heating film formation are obtained.

It was seen that, when H₂O gas is introduced, the film thickness is slightly thin, but the peak wavelength was shifted by the amount greater than or equal to the shift of the peak wavelength due to interference of the film thickness, such that, even when the substrate temperature was heated to 250° C., the same effects as in non-heating are obtained.

Next, H₂O gas was changed to H₂ gas, and a parallel flat plate-shaped cathode capable of supplying power with a direct-current (DC) voltage and a high-frequency (RF) voltage superimposed on each other was used to apply sputtering power with 350 W of high-frequency (RF) power superimposed on 1 kW of DC power from the power source 34 to the cathode 12.

An AZO film was deposited on the alkali-free glass substrate in the same manner as described above, except that constant current control was performed using a current of 4 A.

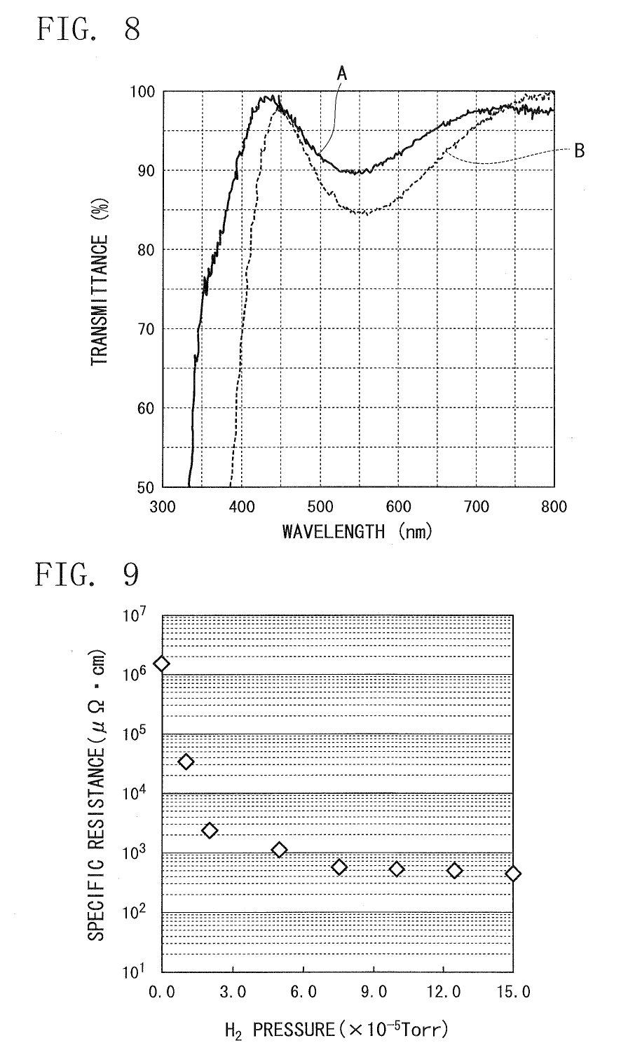

FIG. 8 is a diagram showing the effect of simultaneous introduction of H₂ gas and O₂ gas at the time of heating film formation when the substrate temperature is at 250° C.

In FIG. 8, reference numeral A denotes transmittance of the zinc oxide-based transparent-electroconductive film when H₂ gas is introduced at a partial pressure of 15×10⁻⁵ Torr and O₂ gas is simultaneously introduced at a partial pressure of 1×10⁻⁵ Torr, and reference numeral B denotes transmittance of the zinc oxide-based transparent-electroconductive film when O₂ gas is introduced at a partial pressure of 1×10⁻⁵ Torr.

When H₂ gas and O₂ gas are simultaneously introduced, the film thickness of the transparent-electroconductive film was 211.1 nm.

When only O₂ gas is introduced, the film thickness of the transparent-electroconductive film was 208.9 nm.

From FIG. 8, it was seen that, when H₂ gas and O₂ gas are simultaneously introduced, the peak wavelength is shifted by the amount greater than or equal to the shift of the peak wavelength due to interference of the film thickness compared to a case where only O₂ gas is introduced.

It was also seen that transmittance is improved.

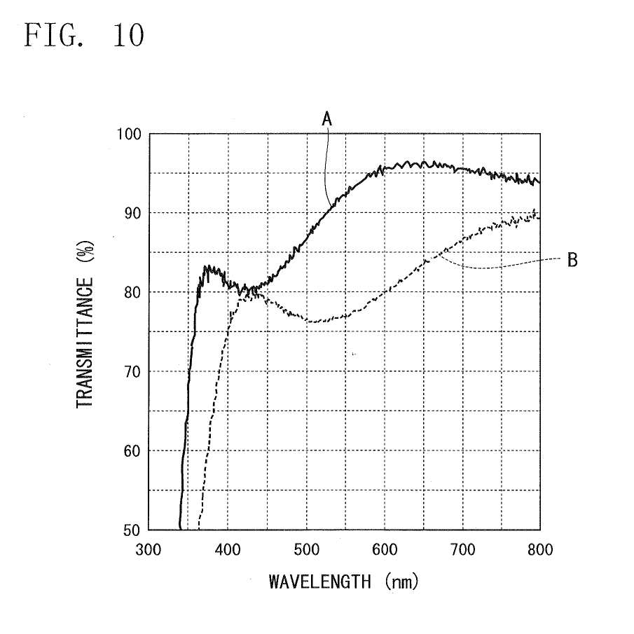

FIG. 9 is a diagram showing the effect of simultaneous introduction of H₂ gas and O₂ gas at the time of heating film formation when the substrate temperature is at 250° C. FIG. 9 shows the specific resistance of the zinc oxide-based transparent-electroconductive film when the partial pressure of O₂ gas was fixed at 1×10⁻⁵ Torr (a partial pressure at a flow rate), and the partial pressure of H₂ gas was changed in a range of 0 to 15×10⁻⁵ Torr (a partial pressure at a flow rate).

The film thickness of the transparent-electroconductive film was approximately 200 nm.

From this drawing, it was seen that, when the partial pressure of H₂ gas is in a range of 0 Torr to 2.0×10⁻⁵ Torr, specific resistance rapidly decreases, and if the partial pressure of H₂ gas exceeds 2.0×10⁻⁵ Torr, specific resistance is stabilized.

When no reactive gas is introduced on the same condition, the specific resistance of the transparent-electroconductive film is 422 μΩ·cm. From this, it was seen that, even when H₂ gas and O₂ gas are simultaneously introduced, degradation of specific resistance is small.

In particular, a transparent-electroconductive film which is used in a display or the like has to have high transmittance in the visible light area and low resistance.

A transparent electrode of a general display has to have specific resistance less than or equal to 1.0×10³ μΩ·cm.

In FIG. 9, specific resistance is less than or equal to 1.0×10³ μΩ·cm when the pressure of H₂ gas is greater than or equal to 5.0×10⁻⁵ Torr.

The pressure of O₂ gas is 1×10⁻⁵ Torr, and thus in order that specific resistance is less than or equal to 1.0×10³ μΩ·cm, it is seen that it is preferable that the condition satisfy R=P_{H2}/P_{O2}≧5.

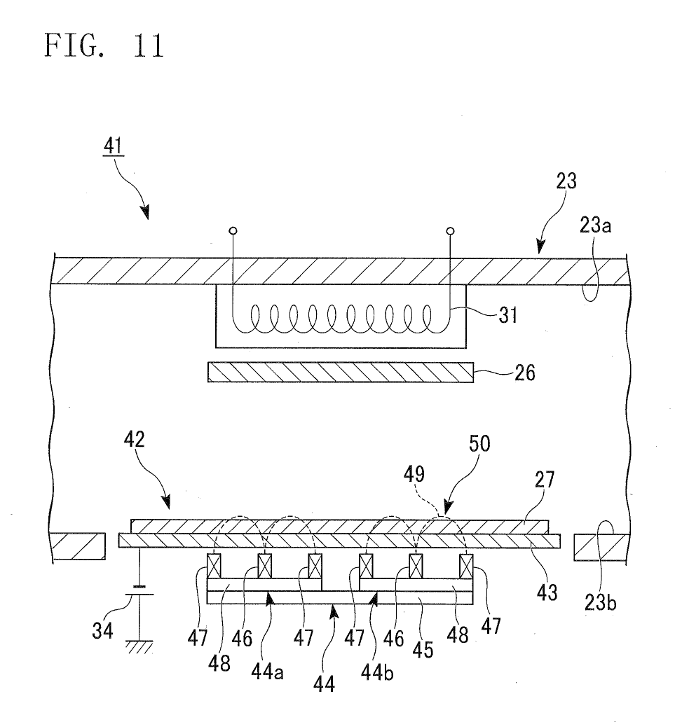

FIG. 10 is a diagram showing the effect of H₂ gas at the time of non-heating film formation.

In FIG. 10, reference numeral A denotes transmittance of the zinc oxide-based transparent-electroconductive film when H₂ gas is introduced at a partial pressure of 3×10⁻⁵ Torr, and reference numeral B denotes transmittance of the zinc oxide-based transparent-electroconductive film when O₂ gas is introduced at a partial pressure of 1.125×10⁻⁵ Torr.

As the cathode, an opposed cathode was used which applies a direct-current (DC) voltage.

When H₂ gas is introduced, the film thickness of the transparent-electroconductive film was 191.5 nm, and the specific resistance of the transparent-electroconductive film was 913 μΩcm.

When O₂ gas is introduced, the film thickness of the transparent-electroconductive film was 206.4 nm, and the specific resistance of the transparent-electroconductive film was 3608 μΩcm.

From FIG. 10, it was seen that, if H₂ gas is introduced, the peak wavelength of transmittance can be changed without changing the film thickness.

It was also seen that transmittance increases compared to a case where O₂ gas is introduced.

With the above, it was seen that, in the process in which H₂ gas is introduced, if the H₂ gas introduction amount is optimized, a zinc oxide-based transparent-electroconductive film having high transmittance and low specific resistance is obtained.

According to the touch panel manufacturing method of the first embodiment, sputtering is carried out in the reactive gas atmosphere containing two or three gases selected from the group consisting of the hydrogen gas, the oxygen gas, and water vapor. Thus, it is possible to easily form the zinc oxide-based anti-reflective film 12 having excellent transparency thereof to visible light beams and the zinc oxide-based transparent-electroconductive film 13 having low specific resistance and excellent transparency thereof to visible light beams.

With the film formation apparatus of the first embodiment, the gas introduction section 35 includes the sputtering gas introduction section 35a which introduces the sputtering gas, such as Ar, the hydrogen gas introduction section 35b which introduces the hydrogen gas, the oxygen gas introduction section 35c which introduces the oxygen gas, and the water vapor introduction section 35d which introduces water vapor.

The introduction sections 35a to 35d are controlled to perform control such that the atmosphere when the zinc oxide-based anti-reflective film 12 or transparent-electroconductive film 13 is formed is set to the reactive gas atmosphere in which the ratio of a reductive gas to an oxidative gas is balanced.

Therefore, it is possible to form the zinc oxide-based anti-reflective film or transparent-electroconductive film simply by improving a part of a conventional film formation apparatus.

### Second Embodiment

FIG. 11 is a sectional view showing a main part of a film formation chamber of an interback magnetron sputtering apparatus (film formation apparatus) which is used for a touch panel manufacturing method according to a second embodiment of the present invention.

A magnetron sputtering apparatus 41 of the second embodiment is different from the sputtering apparatus 21 of the first embodiment in that a sputtering cathode mechanism (target holding section) 42 is provided vertically at the second lateral surface 23b of the film formation chamber 23 to hold the target 27 made of a zinc oxide-based material and to generate a desired magnetic field.

The sputtering cathode mechanism 42 includes a rear plate 43 to which the target 27 is bonded (fixed) via a soldering material or the like, and a magnetic circuit (magnetic field generating portion) 44 which is disposed along the rear surface of the rear plate 43.

The magnetic circuit 44 has a function of generating a horizontal magnetic field on the surface of the target 27.

In the magnetic circuit 44, a plurality of magnetic circuit units (in FIG. 11, two magnetic circuit units) 44a and 44b are connected to each other by a bracket 45 and formed as a single body.

Each of the magnetic circuit units 44a and 44b includes a first magnet 46, second magnets 47, and a yoke 48 on which the magnets 46 and 47 are mounted.

At a position near the rear plate 43 (a position facing the rear plate 43), the first magnet 46 and the second magnet 47 have different polarities.

In the magnetic circuit 44, magnetic fields are generated by the first magnet 46 and the second magnet 47 having different polarities as indicated by magnetic field lines 49.

Thus, a position 50 where a vertical magnetic field is 0 (a horizontal magnetic field is maximized) occurs on the surface of the target 27 between the first magnet 46 and the second magnet 47.

High-density plasma is generated at the position 50, improving the film formation rate.

The maximum value of the intensity of the horizontal magnetic field on the surface of the target 27 is preferably greater than or equal to 600 gauss.

If the maximum value of the intensity of the horizontal magnetic field is set to be greater than or equal to 600 gauss, the electric discharge voltage can be decreased.

In the film formation apparatus for the transparent-electroconductive film of the second embodiment, the same effects as in the sputtering apparatus of the first embodiment can be obtained.

Moreover, if the sputtering cathode mechanism 42 is vertically provided at the second lateral surface 23b of the film formation chamber 23 to generate a desired magnetic field, the sputtering voltage is less than or equal to the 340 V, and the maximum value of the intensity of the horizontal magnetic field on the surface of the target 27 is greater than or equal to 600 gauss, it is possible to form a zinc oxide-based anti-reflective film or transparent-electroconductive film with arranged crystal lattices.

The zinc oxide-based anti-reflective film or transparent-electroconductive film is scarcely oxidized even when annealing is carried out at a high temperature after film formation, and can suppress a decrease in transmittance or an increase in specific resistance, and it is possible to obtain a zinc oxide-based anti-reflective film or transparent-electroconductive film having excellent heat resistance.

### INDUSTRIAL APPLICABILITY

As described above in detail, the present invention is applicable to a touch panel manufacturing method capable of decreasing the specific resistance of a zinc oxide-based transparent-electroconductive film and maintaining transparency to visible light beams, even when an optical film, such as an anti-reflective film, is provided, forming a transparent-electroconductive film or an optical film by a single apparatus, and forming a multilayered optical film or a multilayered optical film and a transparent-electroconductive film by using one type of target and changing the type of gas to be introduced.

What is claimed is:

1. A touch panel manufacturing method, the touch panel including a transparent substrate having a main surface on which a transparent-electroconductive film is formed, the method comprising:
disposing the transparent substrate;
forming the transparent-electroconductive film on the transparent substrate by carrying out sputtering using a target made of a zinc oxide-based material in a reactive gas atmosphere containing two or three gases selected from a group consisting of hydrogen gas, oxygen gas, and water vapor, on the main surface of the transparent substrate.

2. The touch panel manufacturing method, according to claim 1, wherein the touch panel includes: a first transparent substrate on which the transparent-electroconductive film is formed; and a second transparent substrate on which the transparent-electroconductive film is formed, and wherein the first transparent substrate and the second transparent substrate are arranged to face each other at a predetermined gap so that the transparent-electroconductive film of the first transparent substrate and the transparent-electroconductive film of the second transparent substrate are arranged to face each other and separated from each other by a predetermined gap.

3. The touch panel manufacturing method, according to claim 2, further comprising:
forming an optical film on one of the first transparent substrate and the second transparent substrate by carrying out sputtering using a target made of a zinc oxide-based material in a reactive gas atmosphere containing two or three gases selected from a group consisting of hydrogen gas, oxygen gas, and water vapor; and
subsequently forming the transparent-electroconductive film on the optical film.

4. The touch panel manufacturing method, according to claim 3, wherein
the optical film is formed by sputtering using a target made of a first zinc oxide-based material in a reactive gas atmosphere containing two or three gases selected from a group consisting of hydrogen gas, oxygen gas, and water vapor; and
the transparent-electroconductive film is subsequently formed on the optical film by sputtering using a target made of a second zinc oxide-based material in a reactive gas atmosphere containing two or three gases selected from a group consisting of hydrogen gas, oxygen gas, and water vapor.

5. The touch panel manufacturing method according to claim 1, wherein a ratio R(P_{H2}/P_{O2}) of a partial pressure (P_{H2}) of the hydrogen gas to a partial pressure (P_{O2}) of the oxygen gas satisfies
R=P_{H2}/P_{O2}≧5.

6. The touch panel manufacturing method according to claim 1, wherein a sputtering voltage when the sputtering is carried out is less than or equal to 340 V.

7. The touch panel manufacturing method according to claim 1, wherein a sputtering voltage when the sputtering is carried out is a voltage in which a high-frequency voltage is superimposed on a direct-current voltage.

8. The touch panel manufacturing method according to claim 1, wherein a maximum value of an intensity of a horizontal magnetic field on a surface of the target is greater than or equal to 600 gauss.

9. The touch panel manufacturing method according to claim 1, wherein the zinc oxide-based material is aluminum-added zinc oxide or gallium-added zinc oxide.

10. A film formation apparatus manufacturing a touch panel, comprising:
a vacuum chamber;
a target holding section holding a target in the vacuum chamber; and
a power source applying a sputtering voltage to the target, wherein the vacuum chamber has two or more of a hydrogen gas introduction section, an oxygen gas introduction section, and a water vapor introduction section.

11. The film formation apparatus according to claim 10, wherein the power source uses both a direct-current power source and a high-frequency power source.

12. The film formation apparatus according to claim 10, further comprising:
a magnetic field generation section provided in the target holding section, generating a horizontal magnetic field having a maximum intensity value greater than or equal to 600 gauss on a surface of the target.
